(19) United States
(12) Patent Application Publication
(10) Pub. No.: US 2011/0140238 A1
(43) Pub. Date: Jun. 16, 2011

(54) SEMICONDUCTOR DEVICE AND MANUFACTURING METHOD THEREOF

(75) Inventors: Katsuaki NATORI, Yokohama-shi (JP); Koji YAMAKAWA, Tokyo (JP); Takayuki OKADA, Kawasaki-shi (JP); Iwao KUNISHIMA, Yokohama-shi (JP); Hiroshi NAKAKI, Yokkaichi-shi (JP)

(73) Assignee: KABUSHIKI KAISHA TOSHIBA, Tokyo (JP)

(21) Appl. No.: 12/887,111

(22) Filed: Sep. 21, 2010

(30) Foreign Application Priority Data
Dec. 14, 2009 (JP) 2009-283006

(51) Int. Cl. H01L 29/92; H01L 21/02

(52) U.S. Cl. 257/532; 438/3; 257/E29.343; 257/E21.008

(57) ABSTRACT

According to an embodiment, there is provided a method for manufacturing a semiconductor device having a ferroelectric capacitor including a lower electrode, an upper electrode, and a dielectric film provided between the lower electrode and the upper electrode. The method includes firstly forming a conductive film on the lower electrode. Next, it includes forming an SRO film on the conductive film. Then, it includes performing a first thermal treatment crystallizing the SRO film. Then, it includes forming a first PZT film on the SRO film by the sputtering method and performing a second thermal treatment crystallizing the first PZT film. Then, it includes forming the second PZT film on the first PZT film by the CVD method.

### CROSS-REFERENCE TO RELATED APPLICATION

This application is based upon and claims the benefit of priority from the prior Japanese Patent Application No. 2009-283006, filed on Dec. 14, 2009, the entire contents of which are incorporated herein by reference.

### FIELD

Embodiments described herein relate generally to a semiconductor device, more specifically, to a semiconductor device having a ferroelectric capacitor and a manufacturing method thereof.

### BACKGROUND

FeRAM (ferroelectric random access memory) which is a memory using a capacitor, for example, a nonvolatile memory using a ferroelectric thin film, replaces the capacitor portion of a DRAM with a ferroelectric capacitor. The FeRAM has the following features and is expected as a next-generation memory.
Write and erase at high speed. A DRAM-level write time (100 ns or less) is enabled by making cells smaller.
A nonvolatile memory. That is, unlike an SRAM and a DRAM, memory contents are not lost even when a power source is turned off.
The number of rewritable operations is large. 10¹² or more rewrite operations are enabled by devising a ferroelectric material (such as SBT) and an electrode material (such as IrOₓ, RuOₓ, and SrRuO₃).
In principle, higher density and higher integration are enabled so that an integration degree equal to a DRAM can be obtained.
The internal write voltage can be about 2 V so that an operation with low power consumption is enabled.
Information rewrite by random access is enabled.

The FeRAM having the above advantages uses a ferroelectric thin film, such as PZT(Pb(ZrₓTi₁₋ₓ)O₃), BIT(Bi₄Ti₃O₁₂), and SBT(SrBi₂Ta₂O₉), for the capacitor portion. Any of the materials also has a crystalline structure called a perovskite structure with an oxygen octahedron as a basic structure. In the perovskite structure, a metal atom A is arranged at each vertex (A site) of a cubic crystal system, an oxygen atom O is arranged at each face center thereof, and a metal atom B is arranged at a body center (B site) thereof.

Unlike a silicon oxide film which has conventionally been used as an insulating film, these materials do not exhibit ferroelectricity which is the feature of these materials in an amorphous state. This is because polarization of a ferroelectric substance such as PZT occurs as displacement of the charge centers of negative ions and positive ions has two metastable conditions and the metastable conditions occur by crystallization.

Accordingly, to obtain a ferroelectric capacitor having excellent characteristics, it is necessary to form a ferroelectric film having excellent crystallinity. In other words, to use the above material as a ferroelectric substance, a crystallization process (for example, crystallization thermal treatment at high temperature (annealing) or in-situ crystallization process at high temperature) is necessary. Depending on material, temperatures requirement for crystallization are typically at least 400° C. to 700° C.

Various ferroelectric film forming methods, such as a laser ablation method, a vacuum evaporation method, and an MBE method, have been studied. As those which are in practical use, there are a CVD (chemical vapor deposition) method, the sputtering method, and a CSD (chemical solution deposition) method.

The ferroelectric material actually used in the FeRAM is PZT or SBT. PZT has been studied for a thin film forming method from early on, also with many research examples using the CVD method, the sputtering method, and a sol-gel method, and is the first material to be made practical as a FeRAM.

Hereinafter, taking PZT as a representative ferroelectric material as an example, its features will be described. PZT has the following advantages.
The crystallization temperature is relatively low (about 600° C.).
The polarization amount is large. A residual polarization value of about 20 μC/cm² is obtained.
The coercive electric field is relatively small. Therefore, polarization inversion at low voltage is enabled. It should be noted that the coercive electric field is an electric field when polarization is zero on a hysteresis curve.
By changing the Zr/Ti composition ratio, in addition to the crystalline temperature, a structural characteristic (such as grain size and grain shape), and a ferroelectric characteristic (such as a polarization amount, a coercive electric field, a fatigue characteristic, and a leak current) can be controlled.
Due to wide element acceptability owned by the perovskite structure, Pb located at the A site can be substituted by an element such as Sr, Ba, Ca, or La, and Zr or Ti located at the B site can be substituted by an element of Nb, W, Mg, Co, Fe, Ni, or Mn, respectively. This can largely change the crystalline structure, the structural characteristic, and the ferroelectric characteristic.

As described above, as the crystallization temperature of PZT is about 600° C., in order to obtain a crystallized PZT film, it is necessary to form a film at 600° C. or higher, or to perform a thermal treatment at 600° C. or higher after film forming.

Of the PZT film forming methods, the sputtering method has been practically used most often. There are mainly two methods using the sputtering method. One is a method performing high-temperature film formation enabling in-situ crystallization. The other is a method performing annealing for crystallization after film deposition at room temperature.

When the former high-temperature film deposition is performed, as Pb has high volatility, it is desorbed from the inside of the formed PZT film and the target PZT. Therefore, there is a problem in composition controllability. Further, to prevent Pb desorption at the time of the high-temperature film deposition, it is also considered to use a multi-target sputtering device. However, as the distance between a target and a substrate is long, the film deposition speed is decreased, resulting in decrease of productivity.

In the case of the latter method performing annealing after film deposition, as Pb is desorbed at the time of annealing, a PZT film having an increased Pb composition is previously formed so as to obtain a proper Pb composition after annealing. This provides the PZT film excellent crystallinity. However, when a thick PZT film is formed, the control of the Pb composition becomes difficult so that stable film forming cannot be performed. In other words, the Pb composition of the PZT film is changed with time to perform sputtering. In addition, as a void due to Pb desorption occurs at the time of annealing, the film density of the PZT film is lowered. When a point defect is caused by Pb desorption, a fixed charge is created in the PZT film, resulting in deteriorated electric characteristic.

As another PZT film forming method, there is the CVD method. According to the CVD method, a PZT film having a desired Pb composition can be formed at a film forming temperature higher than the crystallization temperature (600° C.) by controlling the amount of supply of a source material. In other words, in the case of the CVD method, composition control is easy. Further, Pb desorption from the PZT film can also be prevented by controlling Pb partial pressure.

However, there are the following problems as the disadvantages of the CVD method. First, as an oxidation source (e.g., O₂) is used, the surface of an Ir film (lower electrode) as the underlayer of the PZT film is oxidized to be IrOₓ. When the Ir film is oxidized in this manner, the amount of read signal from the FeRAM cell is reduced. This is because although the deposition of the PZT film with (111) orientation using the (111) orientation of Ir as a crystalline nucleus is desirable from the viewpoint of obtaining excellent characteristics, it becomes difficult when the Ir film is oxidized.

Second, there is a problem that crystallization is impeded by taking in carbon (C) or the like included in the source material as impurities in the PZT film. However, a method avoiding this problem by forming a PZT film at two stages has been known. In other words, first, at an early stage deposition for the PZT film, crystallization is promoted by lowering the O₂ partial pressure and increasing the Pb concentration to form the PZT thin film (a thickness of about several nm). Thereafter, the PZT thick film of stoichiometry is formed over the PZT thin film under the conditions of the high O₂ partial pressure. The thick PZT film can prevent void occurrence and is excellent in electric characteristic. However, when the PZT film forming by the two-stage CVD method is performed, so-called memory effect in which the previous film forming conditions change the following film deposition conditions occurs at the time of changing the concentration of a source gas during the PZT film deposition, resulting in deterioration of reproductivity of the PZT film.

As described above, according to the sputtering method, the PZT film which reduces impurities and is excellent in crystallinity can be formed, and the oxidation of the lower electrode of the capacitor can be prevented. However, there is a problem that Pb is desorbed and a void occurs due to the thermal treatment after film deposition. On the other hand, according to the CVD method, composition control is relatively easy, Pb desorption can be prevented, and the film forming rate is also high. However, as the lower electrode is oxidized, the PZT film which has excellent characteristics and in (111) orientation is hard to be formed.

Accordingly, the following manufacturing method of a ferroelectric capacitor of an FeRAM is disclosed in Japanese Patent Application Laid-open Publication No. 2008-124329. In this method, first, a PZT thin film is formed as a seed layer by the sputtering method, and then, a PZT film (bulk layer) is formed on the PZT film as the seed layer by the CVD method. As the sputtering method is used for forming the seed layer, the oxidation of the lower electrode can be prevented and the PZT film excellent in crystallinity can be formed. Then, as the CVD method is used for forming the PZT film as the bulk layer, the film deposition rate is high and composition controllability is excellent. However, as the conductive film (such as the Pt film and the Ir film) as the lower electrode and the PZT film have different crystalline structures, the PZT film having sufficient crystallinity cannot be obtained.

### BRIEF DESCRIPTION OF THE DRAWINGS

FIG. 1A is a cross-sectional view showing an FeRAM manufacturing process according to an embodiment of the present invention;

FIG. 1B is a cross-sectional view showing an FeRAM manufacturing process according to an embodiment of the present invention, following FIG. 1A;

FIG. 1C is a cross-sectional view showing an FeRAM manufacturing process according to an embodiment of the present invention, following FIG. 1B;

FIG. 1D is a cross-sectional view showing an FeRAM manufacturing process according to an embodiment of the present invention, following FIG. 1C;

FIG. 1E is a cross-sectional view showing an FeRAM manufacturing process according to an embodiment of the present invention, following FIG. 1D;

FIG. 1F is a cross-sectional view showing an FeRAM manufacturing process according to an embodiment of the present invention, following FIG. 1E;

FIG. 1G is a cross-sectional view showing an FeRAM manufacturing process according to an embodiment of the present invention, following FIG. 1F;

FIG. 2 is a diagram showing the relation between the film thickness of a seed PZT film and the amount of read signal of the FeRAMs;

FIG. 3 is a diagram showing PZT (111) XRD intensities when the thickness of an SRO film is changed; and

FIG. 4 is a diagram showing PZT (111) XRD intensities when the thickness of a Ti film is changed.

### DETAILED DESCRIPTION

According to an embodiment, there is provided a method for manufacturing a semiconductor device having a ferroelectric capacitor including a lower electrode, an upper electrode, and a dielectric film provided between the lower electrode and the upper electrode. The method includes firstly forming a conductive film on the lower electrode. Next, it includes forming an SRO film on the conductive film. Then, it includes performing a first thermal treatment crystallizing the SRO film. Then, it includes forming a first PZT film on the SRO film by the sputtering method and performing a second thermal treatment crystallizing the first PZT film. Then, it includes forming the second PZT film on the first PZT film by the CVD method.

Hereinafter, a semiconductor device and a manufacturing method thereof according to an embodiment of the present invention will be described with reference to the drawings. Structure elements having the similar function in the respective drawings are indicated by same reference numerals and the detailed description will not be repeated.

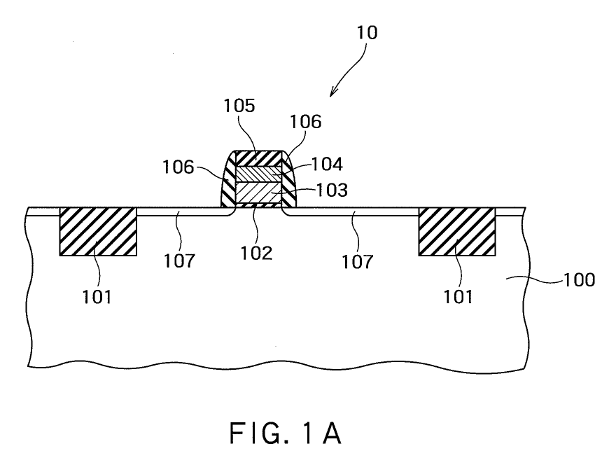

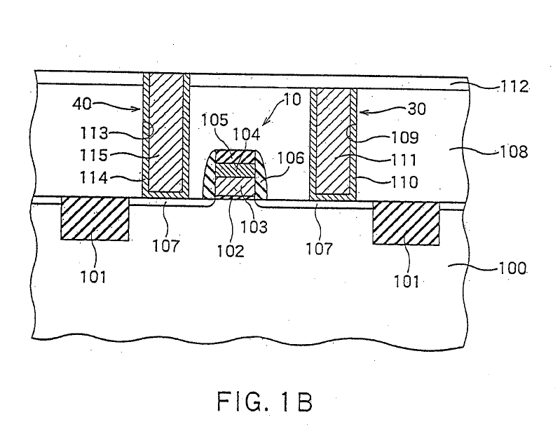

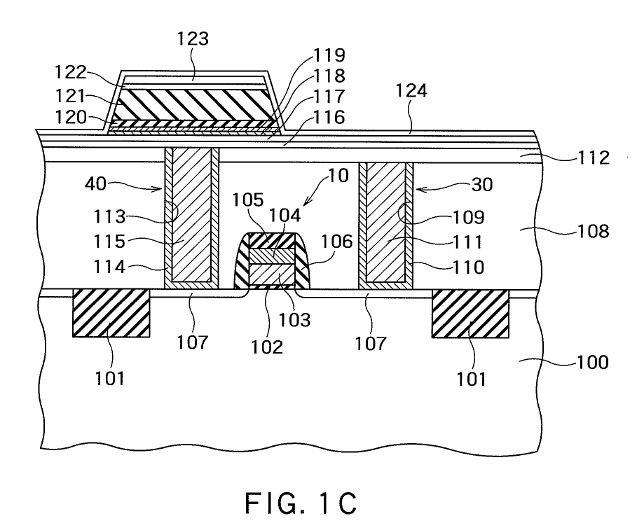

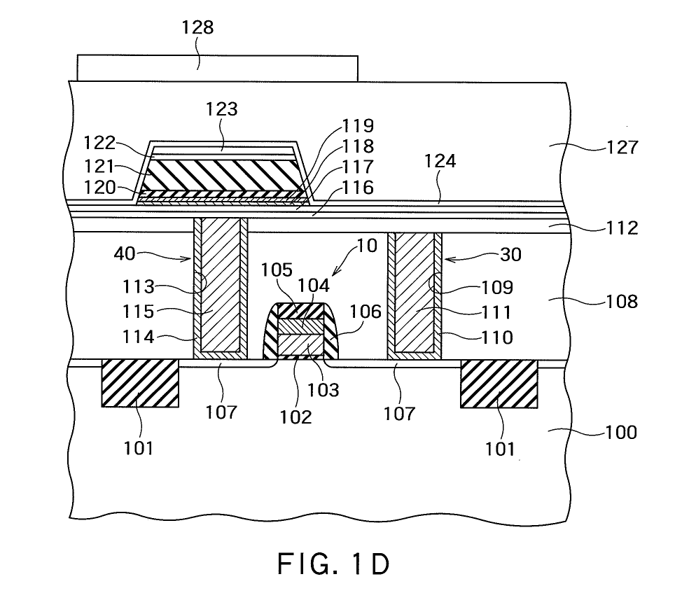

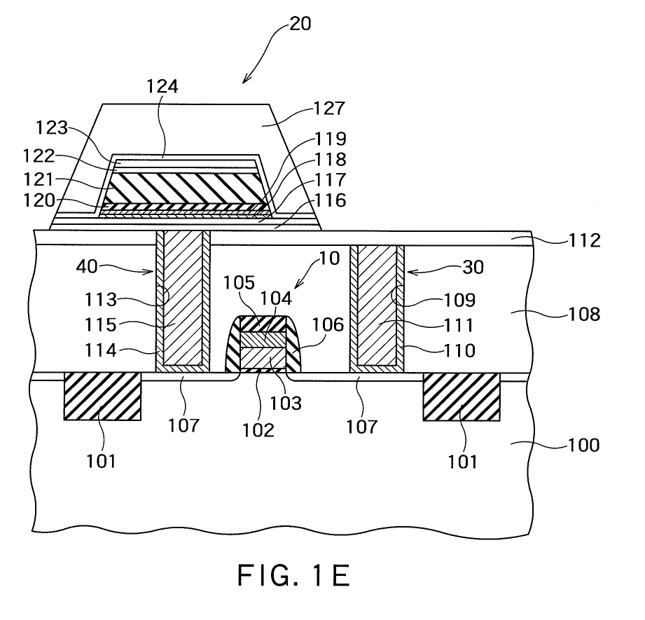

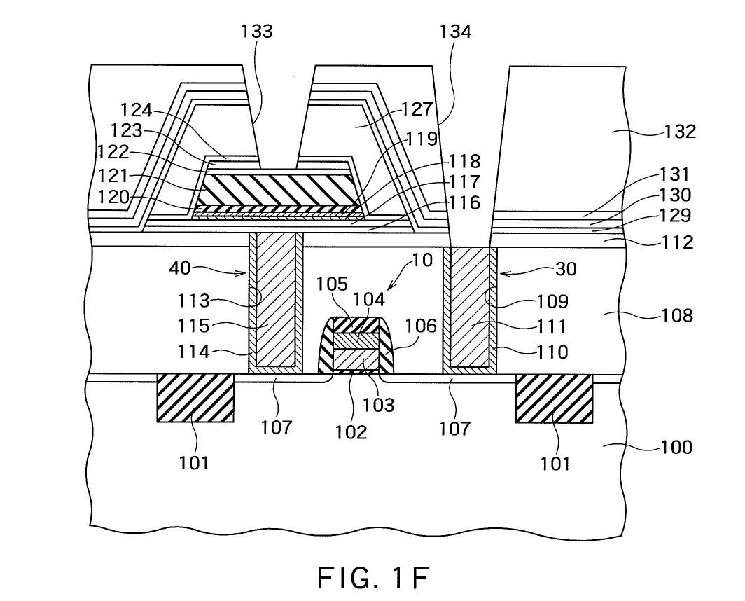

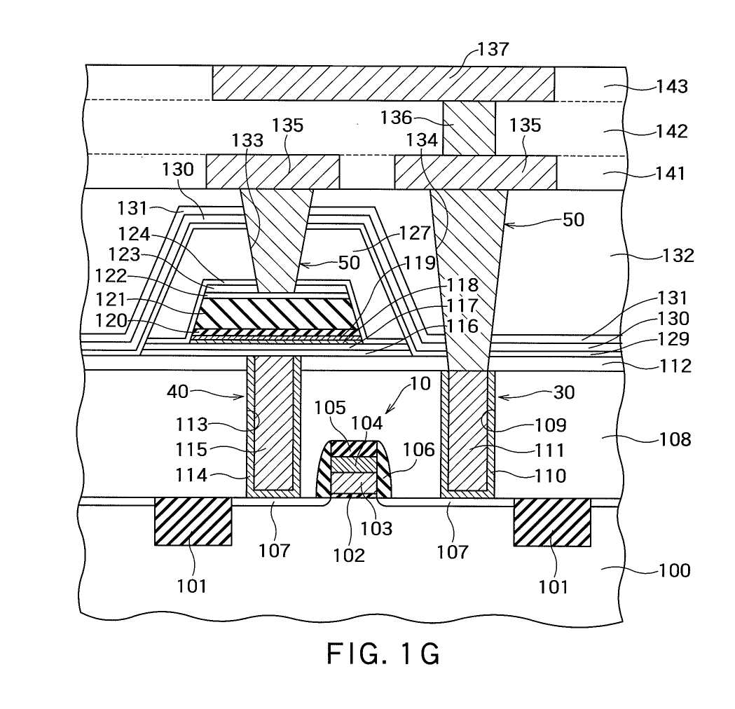

A COP (capacitor on plug) type FeRAM manufacturing method according to this embodiment will be described with reference to FIGS. 1A to 1G.

(1) As seen from FIG. 1A, element isolation regions 101 are formed in outer periphery portions surrounding a transistor active region over the surface of a p-type silicon substrate (semiconductor substrate) 100 by the STI (shallow trench isolation) method. More specifically, after trenches for burying element isolation insulating films are formed into the outer periphery portions, silicon oxide films (SiO₂) are filled into the trenches to form the element isolation regions 101.

(2) Next, a transistor (MOSFET) for performing a switch operation is manufactured in the transistor active region.

(2-1) A silicon oxide film 102 having a thickness of, e.g., about 60 Å, is formed on the entire surface of the p-type silicon substrate 100 by the thermal oxidation method. The silicon oxide film 102 is a gate insulating film of the MOSFET.

(2-2) An n+ type polycrystal silicon film 103 into which arsenic (As) is doped is formed on the silicon oxide film 102. Further, a WSiₓ film 104 and a silicon nitride film (SiN) 105 are successively formed on the polycrystal silicon film 103.

(2-3) A stacking film including the silicon oxide film 102, the polycrystal silicon film 103, the WSiₓ film 104, and the silicon nitride film 105 is processed by the typically used optical lithography method and RIE method to form gate stack.

(2-4) After a silicon nitride film is stacked over the gate stack and the p-type silicon substrate 100, side wall insulating films (spacer portions) 106 are formed on the side walls of the gate stack by the side wall leaving method with the RIE.

(2-5) Thereafter, although the description of the detailed process will be skipped, source-drain regions 107 are formed by the known ion implantation method and thermal treatment.

A MOSFET 10 is completed by the above process.

(3) As seen from FIG. 1B, an interlayer insulating film 108 made of a silicon oxide is stacked over the transistor active region and the element isolation regions 101 by the CVD method to fill the transistor 10. Thereafter, the interlayer insulating film 108 is flattened by the CMP method.

(4) As seen from FIG. 1B, a contact hole 109 is formed in the interlayer insulating film 108. One of the source-drain regions 107 of the transistor 10 is exposed from the bottom surface of the contact hole 109.

(5) As seen from FIG. 1B, a thin titanium film is stacked on the inner wall of the contact hole 109 by the sputtering method or the CVD method, and thereafter, a TiN film 110 is formed by performing thermal treatment in forming gas.

(6) As seen from FIG. 1B, tungsten 111 is stacked inside the contact hole 109 by the CVD method. Thereafter, the surface of the interlayer insulating film 108 is flattened by the CMP method to remove the tungsten 111 stacked outside the contact hole 109. This forms a contact plug 30 having tungsten filled into the contact hole 109.

(7) As seen from FIG. 1B, a silicon nitride film (SiN) 112 is stacked on the interlayer insulating film 108 and the contact plug 30 by the CVD method.

(8) As seen from FIG. 1B, a contact hole 113 through the silicon nitride film 112 and the interlayer insulating film 108 is formed. The other source-drain region 107 of the transistor 10 is exposed from the bottom surface of the contact hole 113. Thereafter, in the same manner as the above method, a TiN film 114 is formed on the inner wall of the contact hole 113 to fill tungsten 115 into the contact hole 113. Thereafter, the silicon nitride film 112 is flattened by the CMP method to remove the tungsten 115 stacked outside the contact hole 113. This forms a contact plug 40 having the tungsten filled into the contact hole 113. It should be noted that the contact plug 40 electrically connects a below-described ferroelectric capacitor 20 and the source-drain region 107.

(9) As seen from FIG. 1C, a TiAlN film 116 (e.g., a thickness of 30 nm) is stacked on the silicon nitride film 112 and the contact plug 40 by the sputtering method. The TiAlN film 116 is an oxide barrier film for preventing the tungsten 115 of the contact plug 40 from being oxidized at the time of a below-described thermal treatment.

(10) As seen from FIG. 1C, an Ir film 117 (e.g., a thickness of about 30 nm) is stacked on the TiAlN film 116 by the sputtering method. Further, the forming conditions of the Ir film 117 are as follows. Using the DC sputtering method with an iridium target, film forming is performed for 60 seconds under the conditions of e.g., a power of 0.2 to 3 kW and pressure of 0.5 to 2 Pa to form a film of 100 nm.

(11) As seen from FIG. 1C, a conductive film 118 and an SRO film 119 made of SrRuO₃ and forming the same perovskite structure as PZT are successively formed on the Ir film 117 by the sputtering method. The conductive film 118 is made of titanium (Ti) and has a thickness of e.g., 1.5 nm. The thickness of the SRO film 119 is e.g., 2.5 nm.

(12) The RTA (rapid thermal annealing) is performed in an oxygen atmosphere to crystallize the SRO film 119.

At the time of the RTA, Ti atoms of the conductive film 118 are diffused into the SRO film 119 to promote the crystallization of the SRO film 119 so that the SRO film 119 can be sufficiently crystallized. The RTA is performed under the conditions of e.g., 550° C. and 30 seconds so that the SRO film 119 excellent in crystallinity can be easily formed. The crystallinity of the SRO film as an underlayer is improved in this manner so that the crystallinity of a below-described seed PZT film 120 can also be improved.

The reason why the crystallinity of the SRO is improved by the diffusion of the Ti atoms can be considered as follows. The Ti atoms diffused by the RTA substitute for Ru atoms arranged at the B site of the SRO having the perovskite structure. The Ti atoms which have substituted for the Ru atoms attract O atoms located in the face center of the perovskite crystalline structure. This can be considered to promote the crystallization of the SRO film.

Here, the thickness of the SRO film 119 and the thickness of the conductive film 118 (Ti film) for obtaining an excellent capacitor characteristic will be described.

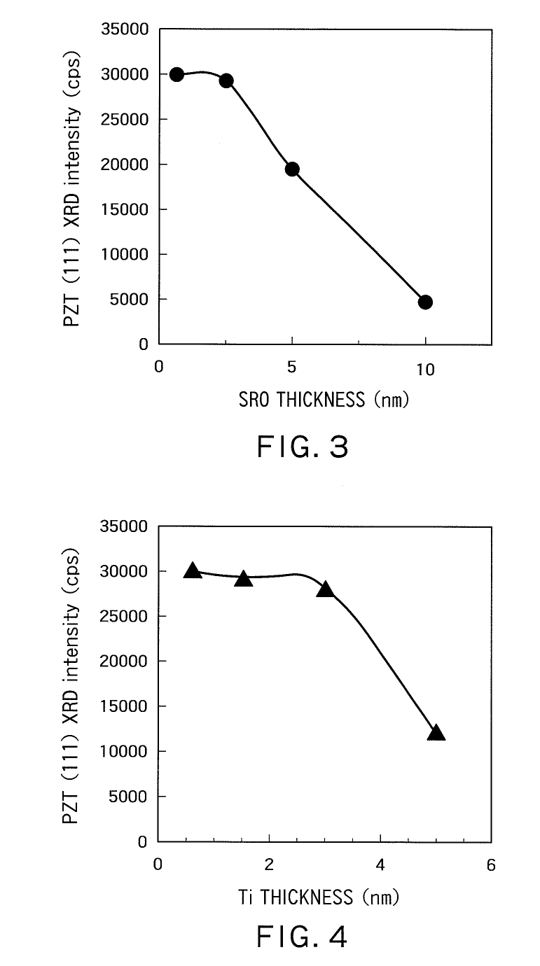

FIG. 3 shows the PZT (111) XRD intensities of the below-described seed PZT film 120 when the thickness of the SRO film 119 is changed. The thickness of the conductive film 118 (Ti film) is 3 nm. As seen from FIG. 3, when the SRO film is thicker than about 3 nm, the PZT (111) XRD intensities is largely lowered. Therefore, the thickness of the SRO film 119 is more desirably 3 nm or lower. In addition, when the SRO film is not provided, the capacitor characteristic is deteriorated, and therefore, the lower limit of the thickness of the SRO film 119 is desirably the thickness of a one-molecular layer of the SRO film. Specifically, the thickness of the SRO film 119 is desirably 0.4 nm or higher.

FIG. 4 shows the PZT (111) XRD intensities of the seed PZT film 120 when the thickness of the conductive film 118 (Ti film) is changed. The thickness of the SRO film 119 is 2.5 nm. As seen from FIG. 4, when the Ti film is thicker than about 3 nm, the PZT (111) intensities is largely lowered. Therefore, the thickness of the Ti film is desirably 3 nm or lower. In addition, when the Ti film is not provided, the capacitor characteristic is deteriorated, and therefore, the lower limit of the thickness of the Ti film is desirably the thickness of a one-molecular layer of the Ti film. Specifically, the thickness of the Ti film is desirably 0.06 nm or more. It should be noted that the above thicknesses are ditto for the conductive film 118 made of below-described metal elements other than titanium.

The conductive film 118 and the SRO film 119 are formed to have thicknesses within the above range so that the (111) intensity of the seed PZT film 120 formed on the SRO film 119 can be increased. In other words, the seed PZT film 120 having excellent characteristics can be obtained. Further, a PZT film (below-described bulk PZT film 121) is formed with the seed PZT film 120 having excellent characteristics as an underlayer so that the ferroelectric capacitor having excellent characteristics can be obtained.

As the amount of Ti included in SRO is increased, the resistance of the SRO film is increased. When the resistance of the SRO film is large, a sufficient voltage cannot be applied to the PZT film, and therefore, a problem that the amount of signal is lowered arises. Accordingly, the thickness of the conductive film 118 is preferably determined so that the SRO film 119 after the RTA can cope with both crystallinity and conductivity. In other words, there is an optimum value according to the film thickness of the SRO film 119 for the thickness of the conductive film 118. Specifically, as described above, when the SRO film 119 of 2.5 nm is formed, the film thickness of the conductive film 118 made of Ti is preferably 1.5 nm.

(13) As seen from FIG. 1C, the seed PZT film 120 (e.g., a thickness of 15 nm) is formed on the SRO film 119 by the sputtering method. It should be noted that as Pb is desorbed by the later thermal treatment process (RTA), the PZT film having excessive Pb is preferably formed as the seed PZT film 120. In addition, although the detail will be described below, the film thickness of the seed PZT film 120 is within the range of 10 nm to 20 nm so that the amount of signal larger than that of the conventional one can be obtained.

(14) The RTA is performed in an oxygen atmosphere to crystallize the seed PZT film 120. The RTA is performed under the conditions of e.g., 600° C. to 700° C. (preferably, 650° C.) and 30 seconds. By the RTA, the PZT film having a perovskite structure can be obtained. It should be noted that when the temperature of the thermal treatment is low, the seed PZT film 120 forms a pyrochlore structure of a paraelectric substance. When the crystalline structure of PZT is changed from the pyrochlore structure to the perovskite structure of the ferroelectric substance, a large energy is necessary. Therefore, desirably, the RTA is performed at temperatures of 600° C. or more, as described above, and PZT having the perovskite structure is formed without stopping, not via the pyrochlore structure.

It should be noted that during the film forming of the seed PZT film 120 having excessive Pb, when the RTA is performed in an oxygen atmosphere, Pb is desorbed, and at the same time, PbO having a low melting point promoting crystallization is added to the seed PZT film 120. As a result, stoichiometry is maintained to obtain a PZT film having excellent crystallinity.

(15) As seen from FIG. 1C, the bulk PZT film 121 which is a dielectric film of the capacitor together with the seed PZT film 120 is formed on the seed PZT film 120 by the CVD method. The bulk PZT film 121 is formed so that the total film thickness of it and the seed PZT film 120 is e.g., 100 nm. Film forming is performed under the conditions of a temperature of 600° C. and pressure of 5 torr. In this manner, it is performed at a temperature higher than the crystallization temperature of PZT. In addition, O₂ is used as an oxygen source and the flow rate is 2 SLM.

It should be noted that in the forming of the bulk PZT film 121, Pb(DPM)₂, Ti(iOPr)₂(DPM)₂, and Zr(DiBM)₄ are used for the source material of the CVD. Here, DPM is dipivaloylmethanate (chemical formula (CH₃)₃CCOCHCOC(CH₃)₃), iOPr is isopropoxide (chemical formula (OCH(CH₃)₂), and DiBM is diisobutylmethanate (chemical formula (CH₃)₂CH(CO)CH(CO—)CH(CH₃)₂)).

(16) As seen from FIG. 1C, an IrO₂ film 122 is formed as an upper electrode on the bulk PZT film 121. Further, the forming conditions of the IrO₂ film 122 are as follows. Using the chemical conversion sputtering method with an iridium target, film forming is performed for 90 seconds under the conditions of power of 0.2 to 2 kW and pressure of 0.5 to 2 Pa to form it to have a thickness of 100 nm.

(17) As seen from FIG. 1C, an Al₂O₃ film 123 (e.g., a thickness of 50 A) is formed as a first protective film on the IrO₂ film 122 by the sputtering method. The Al₂O₃ film 123 is provided to prevent the deterioration of the characteristic of the PZT film due to the diffusion of hydrogen caused in the later-stage process such as the RIE into the PZT film. Later-described Al₂O₃ film 124 (a second protective film), Al₂O₃ film 129 (a third protective film), and Al₂O₃ film 131 (a fourth protective film) are also formed for the same purpose.

(18) By a known method, a processing mask material (not shown) is formed on the Al₂O₃ film 123. More specifically, a silicon oxide film and a photoresist which become processing mask materials are successively stacked on the Al₂O₃ film 123 by e.g., the CVD method. Thereafter, the photoresist is patterned using the optical lithography method and the RIE method. With the patterned photoresist as a mask, the silicon oxide film formed on the Al₂O₃ film 123 is etched. Thereafter, the photoresist is removed to obtain the processing mask material having a desired pattern.

(19) As seen from FIG. 1C, with the processing mask material as a mask, the Al₂O₃ film 123, the IrO₂ film 122, the bulk PZT film 121, the seed PZT film 120, the SRO film 119, and the conductive film 118 are etched by the RIE method.

(20) As seen from FIG. 1C, the Al₂O₃ film 124 (e.g., a thickness of 100 Å) is formed as the second protective film on the side walls of the conductive film 118, the SRO film 119, the seed PZT film 120, the bulk PZT film 121, the IrO₂ film 122, the Al₂O₃ film 123, the upper surface of the Al₂O₃ film 123, and the upper surface of the Ir film 117 by the sputtering method.

(21) As seen from FIG. 1D, a mask oxide film 127 is stacked as a mask material for processing the stacking film (TiAlN film 116 to the SRO film 119) on the Al₂O₃ film 124 by the CVD method. Thereafter, a photoresist is formed on the mask oxide film 127 to form a resist mask 128 processed into a desired pattern by the optical lithography method. With the resist mask 128 as a mask, the mask oxide film 127 is processed by the RIE method.

It should be noted that the mask oxide film 127 is formed by the plasma CVD method using TEOS and oxygen (O₂) for a source material at the film forming temperature of 420° C. In place of the plasma CVD method, the CVD method may be used. In that case, using ozone (O₃), not oxygen, as a source gas, film forming is performed under the conditions of the film forming temperature of 350° C. to 500° C. (particularly preferably, 460° C.).

(22) As seen from FIG. 1E, with the processed mask oxide film 127 as a mask, the Al₂O₃ film 124, the Ir film 117, the TiAlN film 116 are patterned in this order. The forming of the ferroelectric capacitor 20 is completed.

(23) As seen from FIG. 1F, the Al₂O₃ film 129 is formed as the third protective film over the ferroelectric capacitor 20 and the silicon nitride film 112 by an ALD (atomic layer deposition) method. With TMA and O₃ as a raw material, the film forming temperature is 200° C., and the film thickness is 100 Å.

(24) As seen from FIG. 1F, a silicon oxide film 130 (e.g., a thickness of 500 Å) is stacked on the Al₂O₃ film 129 by the CVD method. Thereafter, the Al₂O₃ film 131 is formed as the fourth protective film on the silicon oxide film 130 by the ALD method. With TMA and O₃ as source materials, the film forming temperature is 200° C., and the film thickness is 100 Å.

It should be noted that as the first and the second protective films are relatively close to the PZT film, they are desirably formed by the sputtering method not discharging a gas deteriorating the PZT film such as hydrogen. On the other hand, as the third and the fourth protective films are relatively far from the PZT film, they are desirably formed using the ALD method or the CVD method which can perform dense film forming and secure a high step coverage although it discharges hydrogen.

(25) As seen from FIG. 1F, an interlayer insulating film 132 is stacked on the Al₂O₃ film 131 by the CVD method so as to bury the ferroelectric capacitor 20. Thereafter, the interlayer insulating film 132 is flattened by the CMP method.

(26) As seen from FIG. 1F, the interlayer insulating film 132 is opened in a predetermined position by the optical lithography method and the RIE method to form a contact hole 133 and a contact hole 134. The IrO₂ film 122 which is the upper electrode is exposed from the bottom surface of the contact hole 133. The contact plug 30 is exposed from the bottom surface of the contact hole 134.

(27) As seen from FIG. 1G, aluminum (Al) is filled into the contact hole 133 and the contact hole 134, and then, the surface of the interlayer insulating film 132 is flattened by the CMP method. This completes contact plugs 50. It should be noted that the contact plugs 50 may be formed by burying Al after Nb/NbN films are formed as barrier films on the inner walls of the contact holes 133 and 134.

(28) As seen from FIG. 1G, a silicon oxide film 141 is stacked on the interlayer insulating film 132 and the contact plugs 50.

(29) As seen from FIG. 1G, wiring trenches are formed in the silicon oxide film 141 using the lithography method and the RIE. After A¹ is filled into the wiring trenches, the surface of the silicon oxide film 141 is flattened by the CMP method. This forms first upper wirings 135.

(30) As seen from FIG. 1G, an interlayer insulating film 142 is stacked on the silicon oxide film 141 and the first upper wirings 135. Thereafter, a via hole is formed in the interlayer insulating film 142 by the lithography method and the RIE to fill Al into the via hole. Thereafter, the surface of the interlayer insulating film 142 is flattened by the CMP method. As a result, a via 136 is formed. The via 136 electrically connects a below-described second upper wiring 137 and the first upper wiring 135.

(31) As seen from FIG. 1G, a silicon oxide film 143 is stacked on the interlayer insulating film 142 and the via 136. Thereafter, a wiring trench is formed in the silicon oxide film 143 by the lithography method and the RIE to bury Al into the wiring trench. Thereafter, the surface of the silicon oxide film 143 is flattened by the CMP method. This forms the second upper wiring 137.

Thereafter, although the detailed description is omitted, upper wiring layers are successively formed to complete an FeRAM.

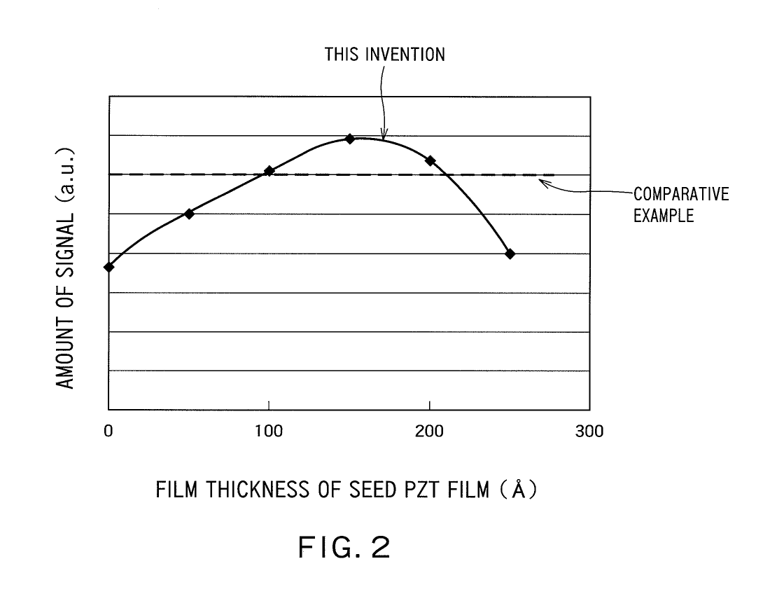

Next, referring to FIG. 2, the characteristic of an FeRAM formed by the method according to an embodiment of the present invention will be described. FIG. 2 is a graph showing the relation between the film thickness of the seed PZT film and the amount of read signal of FeRAMs.

The solid line plots the amount of read signal of an FeRAM formed by the method according to an embodiment of the present invention, and the dashed line plots the amount of read signal of an FeRAM for a reference sample. Here, the dielectric film of a ferroelectric capacitor of the reference sample is made by forming the seed PZT film and the bulk PZT film by the above two-stage CVD method on the lower electrode (Ir film).

It should be noted that in both samples of this embodiment and the reference sample, the total film thickness of the PZT film (the film thickness of the seed PZT film+the film thickness of the bulk PZT film) is fixed to 100 nm.

As seen from FIG. 2, in the range in which the film thickness of the seed PZT film is 10 nm to 20 nm (100 Å to 200 Å), the FeRAM according to this embodiment can obtain the amount of read signal larger than that of the FeRAM of the reference sample. Therefore, the seed PZT film 120 is preferably formed to have a film thickness of 10 nm to 20 nm. In particular, a film thickness is preferably 15 nm.

When the film thickness of the seed PZT film is in a certain range in this manner, the following reasons why the amount of signal larger than the reference sample can be obtained can be considered.

When the film thickness of the seed PZT film 120 is too small (when it is smaller than the lower limit of a certain range), the seed PZT film 120 cannot sufficiently cover the entire surface of the SRO film 119, and therefore, a portion having insufficient crystallinity occurs. As a result, the deterioration of the characteristic (the reduction of the amount of signal) can be considered to occur.

On the other hand, when the film thickness of the seed PZT film 120 is too large (when it is larger than the upper limit of a certain range), Pb desorption caused by the thermal treatment after forming the seed PZT film 120 has distribution with respect to the thickness direction of the seed PZT film 120. As a result, the deterioration of the characteristic (the reduction of the amount of signal) can be considered to occur.

In other words, when the film thickness of the seed PZT film 120 is in a certain range, Pb desorption occurs due to the thermal treatment after film forming, but PZT having very excellent crystallinity is formed in other portion in which Pb desorption does not occur. As described above, this is because the crystallinity of the SRO film 119 as the underlayer of the seed PZT film 120 has the same perovskite structure as the PZT and the crystallinity of the SRO film 119 is improved by diffusing Ti into the SRO film 119. The PZT (the seed PZT film 120) having very excellent crystallinity is used as a crystal nucleus so that the bulk PZT film 121 can be formed by maintaining the crystallinity.

As described above, according to this embodiment, the PZT film having excellent crystallinity can be manufactured with high composition controllability, and therefore, the ferroelectric capacitor having excellent characteristics can be stably obtained. In addition, the amount of read signal larger than the FeRAM according to the comparative example can be obtained by adjusting the film thickness of the seed PZT film. This allows size reduction and higher integration of the FeRAM.

It should be noted that the following various modifications can be made to the above embodiments of the present invention.

In the above embodiments, the COP type FeRAM has been described, but the present invention is not limited to this and is also applicable to semiconductor devices using other ferroelectric capacitor.

In addition, in the above embodiments, the stacking film stacking the conductive film 118 and the SRO film 119 is formed as the underlayer of the seed PZT film 120, but in place of the stacking film, the SRO film into which Ti is doped may also be used.

Further, in the above embodiments, the conductive film 118 made of Ti is formed to promote the crystallization of the SRO film 119, but the conductive film 118 may also be formed using an element other than Ti. Specifically, V, W, Zr, Cr, Mg, Hf, Mo, Mn, Ta, or Nb may also be used.

Furthermore, in the above embodiments, the seed PZT film 120 made of PZT is formed as the seed layer of the bulk PZT film 121, but, as the seed layer, a PLZT ((PbₓLa_{y}) (Zr_{z}Ti_{1-z})O₃) film may also be used. Further, calcium (Ca) or strontium (Sr) may also be doped into the PLZT film.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A method for manufacturing a semiconductor device comprising a ferroelectric capacitor that comprises a lower electrode, an upper electrode, and a dielectric film between the lower electrode and the upper electrode, the method comprising:
forming a conductive film on the lower electrode;
forming a silicon-rich oxide (SRO) film on the conductive film;
performing a first thermal treatment crystallizing the SRO film;
forming a first Lead Zirconate Titanate (PZT) film on the SRO film by the sputtering method;
performing a second thermal treatment crystallizing the first PZT film; and
forming the second PZT film on the first PZT film by the chemical vapor deposition (CVD) method.

2. The method of claim 1, wherein the first PZT film has a thickness of 10 nm to 20 nm.

3. The method of claim 2, wherein the conductive film is a titanium (Ti) film having a thickness of 0.06 nm to 3 nm, and the SRO film has a thickness of 0.4 nm to 3 nm.

4. The method of claim 2, wherein the conductive film comprises at least one of titanium (Ti), vanadium (V), tungsten (W), zirconium (Zr), chromium (Cr), magnesium (Mg), hafnium (Hf), molybdenum (Mo), manganese (Mn), tantalum (Ta), or niobium (Nb).

5. The method of claim 2, wherein the first thermal treatment is executed under the conditions of 550° C. for approximately 30 seconds.

6. The method of claim 2, wherein the second thermal treatment is executed under the conditions of 600° C. to 700° C. for approximately 30 seconds.

7. The method of claim 1, wherein the conductive film is a Ti film having a thickness of 0.06 nm to 3 nm, and the SRO film has a thickness of 0.4 nm to 3 nm.

8. The method of claim 1, wherein the conductive film comprises at least one of Ti, V, W, Zr, Cr, Mg, Hf, Mo, Mn, Ta, or Nb.

9. The method of claim 1, wherein the first thermal treatment is executed under the conditions of 550° C. for approximately 30 seconds.

10. The method of claim 9, wherein the second thermal treatment is executed under the conditions of 600° C. to 700° C. for approximately 30 seconds.

11. The method of claim 1, wherein the second thermal treatment is executed under the conditions of 600° C. to 700° C. for approximately 30 seconds.

12. The method of claim 1, wherein the upper electrode comprises iridium dioxide (IrO₂) on the second PZT film.

13. The method of claim 1, further comprising forming a Lead-Lanthanum-Zirconate-Titanate (PLZT) film in place of the first PZT film.

14. The method of claim 13, wherein calcium (Ca) or strontium (Sr) is doped into the PLZT film.

15. A semiconductor device having a ferroelectric capacitor including a lower electrode, an upper electrode, and a dielectric film provided between the lower electrode and the upper electrode, comprising:
a conductive film formed on the lower electrode;
an SRO film formed on the conductive film and including a structure element of the conductive film;
a first PZT film formed on the SRO film by the sputtering method; and
a second PZT film formed on the first PZT film by the CVD method.

16. The semiconductor device of claim 15, wherein the film thickness of the first PZT film is 10 nm to 20 nm.

17. The semiconductor device of claim 15, wherein the conductive film comprises Ti, the film thickness of the conductive film is 0.06 nm to 3 nm, and the film thickness of the SRO film is 0.4 nm to 3 nm.

18. The semiconductor device of claim 15, wherein the conductive film comprises at least one of Ti, V, W, Zr, Cr, Mg, Hf, Mo, Mn, Ta, or Nb.

19. The semiconductor device of claim 15, further comprising a PLZT film in place of the first PZT film.

20. The semiconductor device of claim 19, wherein calcium (Ca) or strontium (Sr) is doped into the PLZT film.
